(19) United States
(12) Patent Application Publication
(10) Pub. No.: US 2009/0231144 A1
(43) Pub. Date: Sep. 17, 2009

(54) Stealth Detector Metal Detector

(76) Inventor: James Dahl, Boxford, MA (US)

Correspondence Address: Daniel N. Smith, 15 Church Street, Salem, MA, 01970, US

(21) Appl. No.: 12/402,483

(22) Filed: Mar. 11, 2009

Related U.S. Application Data
(60) Provisional application No. 61/035,389, filed on Mar. 11, 2008.

(51) Int. Cl. G01R 33/12; G08B 21/00; G08B 23/00

(52) U.S. Cl. 340/573.1; 340/540; 324/239

(57) ABSTRACT

A portable metal detection system that includes a hand/wrist mounted metal detector with two search coils mounted on the palm side of the detector. The mounted metal detector includes a wireless transmitter and a small rechargeable fuel cell. The detection system also includes a separate housing that contains a wireless receiver, a small rechargeable fuel cell and an adjustable vibration or audio alert circuitry. The separate housing may be worn anywhere on the operator of the system. Once the hand/wrist mounted metal detector detects a metal object, the wireless transmitter sends a signal to the wireless receiver in the separate housing that activates the vibration or audio alert circuitry. The separation of the detection device and the alert circuitry prevents a metal detection detainee from hearing or feeling a metal detection alert.

### CROSS REFERENCE TO RELATED APPLICATION

This application claims the benefit of U.S. Provisional Patent Application No. 61/035,389 filed on Mar. 11, 2008, the contents of which are incorporated herein by reference.

### FIELD OF THE INVENTION

This invention relates to a portable metal detector system that contains a hand/wrist mounted metal detector with a wireless transmitter and one or more wireless receivers located elsewhere on the operator that activate auditory or vibratory alerts.

### BACKGROUND OF INVENTION

Within the field of law enforcement, portable metal detectors are commonly used to detect the presence of metallic objects on a person that is being subject to detainment. Normally the metallic object being searched for is a knife or a gun. Typically, such metal detectors are in the shape of a hand-held “wand.” One problem with this type of wand detector is that it requires an operator to hold the detector in one hand during operation. This method of operation prevents an operator from using both hands to catch a detainee if he or she flees or restrain a detainee if he or she attacks the operator.

In law enforcement, it would be preferable to use a metal detector which did not require the entire usage of an operator's hand during operation. If both hands of the operator are free during operation, it would permit the operator to physical grasp a detainee should the need arise. It may also save the life of a law enforcement officer to have both hands available to counter a physical attack rather than having one hand occupied.

Several hands-free portable metal detectors have been developed. For example, U.S. Pat. No. 6,211,672 discloses a hand/wrist mounted metal detector with an embedded search coil. U.S. Pat. No. 7,221,552 discloses a personal defense device that may incorporate a metal detection device. U.S. Pat. No. 7,081,754 discloses a metal detection system with a magnetometer head coupled to footwear for the detection of metals below a surface of the ground adjacent to a user.

Previous hands-free portable metal detectors have one severe limitation. These metal detectors contain an auditory or vibratory annunciation device that is in close proximity with the metal detection coil. Since the audible or vibration alert must be loud or powerful enough for the operator to hear or feel, and the device producing these alerts is close to the detainee, it is possible that the detainee will hear or feel a positive detection. Thus, when the metal detector coil detects metal on a detainee, the detainee and the operator are both notified of a positive metal detection at the same time.

The present invention discloses a metal detector system with a separate annunciation device located elsewhere on the operator which would allow the operator to be notified of a positive metal detection but prevent the detainee from hearing or feeling when the detector was activated.

### SUMMARY OF THE INVENTION

The subject invention comprises a metal detector adapted for securement around a hand, wherein the metal detector comprises: a first strap, wherein the first strap comprises an adjustable means for connecting a first end of the first strap to a second end of the first strap to form a first loop around the palm of the hand; a second strap wherein the second strap comprises an adjustable means for connecting a first end of the second strap to a second end of second strap to form a second loop around the wrist of the hand; a third strap connecting the first strap and the second strap; a first search coil adapted for detecting metal and a second search coil adapted for detecting metal mounted on the first strap; a metal detection circuit mounted on the first strap, the metal detection circuit including a fuel cell and a wireless transmitter, wherein the metal detection circuit is operationally coupled to the first search coil, the second search coil and the wireless transmitter; further wherein when the first and second search coils detect metal, the first and second search coils send a metal detection signal to the metal detection circuit which sends a transmission signal to the wireless transmitter which emits a wireless signal.

In one embodiment of the subject invention, the metal detector further comprises a wireless headset receiver that emits an audible sound after receiving the wireless signal from the wireless transmitter.

In another embodiment of the subject invention, the metal detector further comprises a receiver housing, wherein the receiver housing comprises an adjustable annunciator electrically coupled to a wireless receiver, further wherein the adjustable annunciator emits an annunciation detectable to an operator after receiving the wireless signal from the wireless transmitter.

In a further embodiment of the subject invention, the receiver housing further comprises a second fuel cell.

In one embodiment of the subject invention, the adjustable means for connecting the first end of the first strap to the second end of the first strap to form the first loop may be selected from the group consisting of Velcro, buckles, magnets, snaps, buttons and tie straps.

In another embodiment of the subject invention, the adjustable means for connecting the first end of the second strap to the second end of the second strap to form the second loop may be selected from the group consisting of Velcro, buckles, magnets, snaps, buttons and tie straps.

In a further embodiment of the subject invention, the fuel cell is rechargeable.

In one embodiment of the subject invention, the wireless transmitter is a Bluetooth transmitter.

In another embodiment of the subject invention, the first strap, the second strap and the third strap comprise a unitary piece.

In a further embodiment of the subject invention, the first strap, the second strap and the third strap are constructed of nylon polypropylene.

In one embodiment of the subject invention, the fuel cell comprises a NiH watch battery.

The subject invention also comprises a method of detecting a metal object on a person, the method comprising the steps of: a) securing a metal detector around a hand of an operator by connecting a first end of a first strap on the metal detector to a second end of the first strap to form a first loop around the palm of the hand; b) connecting a first end of a second strap on the metal detector to a second end of the second strap to form a second loop around the wrist of the hand of the operator; c) attaching a receiver housing to the operator; d) activating the metal detector and the receiver housing; e) passing a first search coil adapted for detecting metal and a second search coil adapted for detecting metal mounted on the first strap over the person; f) detecting metal on the person, wherein the first and second search coils send a metal detection signal to a metal detection circuit on the metal detector which sends a transmission signal to a wireless transmitter in the metal detector circuit which emits a wireless signal; and g) receiving the wireless signal through a wireless receiver in the receiver housing, wherein an adjustable annunciator in the receiver housing emits an annunciation that is detectable to the operator.

In one embodiment of the subject invention, the method further comprises a wireless headset receiver, wherein the wireless headset receiver emits an audible sound after receiving the wireless signal from the wireless transmitter.

In another embodiment of the subject invention, the annunciation is a vibration. In a further embodiment of the subject invention, the annunciation is an audible sound. In one embodiment of the subject invention, the wireless transmitter is a Bluetooth transmitter.

In another embodiment of the subject invention, the method further comprises the step of receiving the wireless signal in a second receiver housing attached to a second operator. In a further embodiment of the subject invention, the method further comprises the step of receiving the wireless signal in a plurality of other receiver housings attached to a plurality of other operators.

In one embodiment of the subject invention, the method further comprises the step of receiving the wireless signal in a cellular phone. In another embodiment of the subject invention, the method further comprises the step of receiving the wireless signal in a GPS device.

There are additional features of the invention that will be described hereinafter and which will form the subject matter of the claims appended hereto. In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

There has thus been outlined, rather broadly, the more important features of the invention in order that the detailed description thereof that follows may be better understood, and in order that the present contribution to the art may be better appreciated. There are additional features of the invention that will be described hereinafter and which will form the subject matter of the claims appended hereto. These together with other objects of the invention, along with the various features of novelty, which characterize the invention, are pointed out with particularity in the claims annexed to and forming a part of this disclosure.

For a better understanding of the invention, its operating advantages and the specific objects attained by its uses, reference should be made to the accompanying drawings and descriptive matter in which there are illustrated preferred embodiments of the invention. Other features and advantages of the present invention will become apparent from the following description of the preferred embodiment(s), taken in conjunction with the accompanying drawings, which illustrate, by way of example, the principles of the invention.

### BRIEF DESCRIPTION OF THE DRAWINGS

Advantages of the present invention will be apparent from the following detailed description of exemplary embodiments thereof, which description should be considered in conjunction with the accompanying drawings, in which:

FIG. 1 illustrates an isometric view of the stealth detector metal detector in an open position.

FIG. 2 illustrates a top view of the stealth detector metal detector on an operator's hand.

FIG. 3 illustrates a bottom view of the stealth detector metal detector on an operator's hand.

FIG. 4 illustrates a side view of the stealth detector metal detector in the closed position.

FIG. 5 illustrates a side view of a wireless headset receiver.

FIG. 6 illustrates a front view of a receiver housing.

FIG. 7 illustrates a back view of the receiver housing.

### DETAILED DESCRIPTION OF THE PREFERRED EMBODIMENTS

While several variations of the present invention have been illustrated by way of example in preferred or particular embodiments, it is apparent that further embodiments could be developed within the spirit and scope of the present invention, or the inventive concept thereof. However, it is to be expressly understood that such modifications and adaptations are within the spirit and scope of the present invention, and are inclusive, but not limited to the following appended claims as set forth.

The disclosed invention comprises a metal detection system comprising a hand/wrist mounted detector with two search coils mounted on the palm side of the detector. In one embodiment of the subject invention, the top side of the detector also contains: a metal detection circuit; a wireless transmitter; and a small rechargeable fuel cell. The metal detection system also comprises a separate housing that may be worn anywhere on the user. In another embodiment of the subject invention, this separate housing contains: an adjustable vibration and audio alert circuitry; a built-in wireless receiver; and a small rechargeable fuel cell.

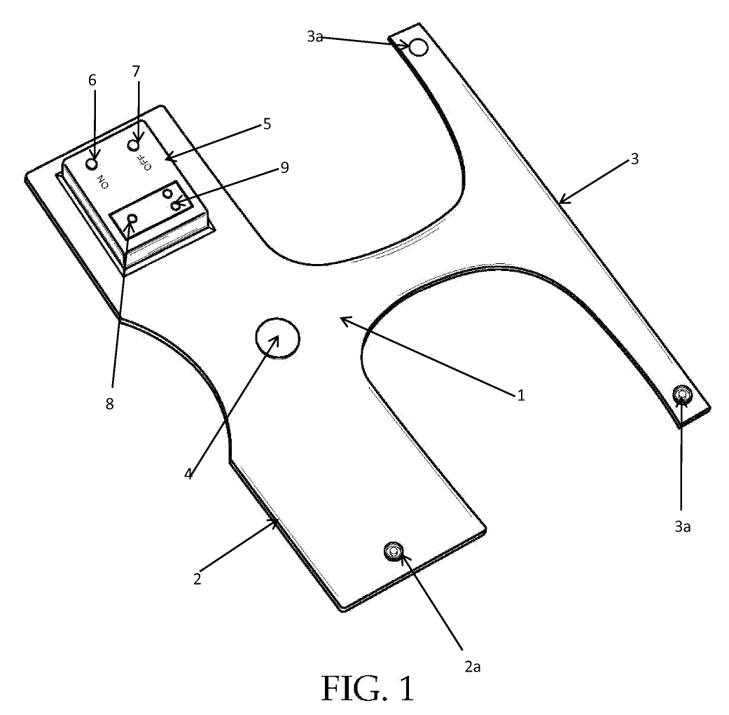

FIG. 1 illustrates an embodiment of the stealth detector metal detector 1 in an open position before being mounted on an operator's wrist and hand. The hand/wrist mounted detector 1 contains a hand-mounting strap 2 with button snaps 2a to form a loop around the palm of an operator's hand and a wrist mounting strap 3 with button snaps 3a to form a loop around the wrist of an operator's hand. In other embodiments of the subject invention, the hand-mounting strap 2 and the wrist mounting strap 3 may be connected by other fasteners such as Velcro®, buckles, magnets, snaps, buttons and tie straps. In another embodiment of the subject invention, one or both ends of the hand-mounting strap 2 and the wrist mounting strap 3 may comprise an elastic material known to those skilled in the art. This elastic material may be stretchable to allow the straps to be fitted over an operator's hand and wrist.

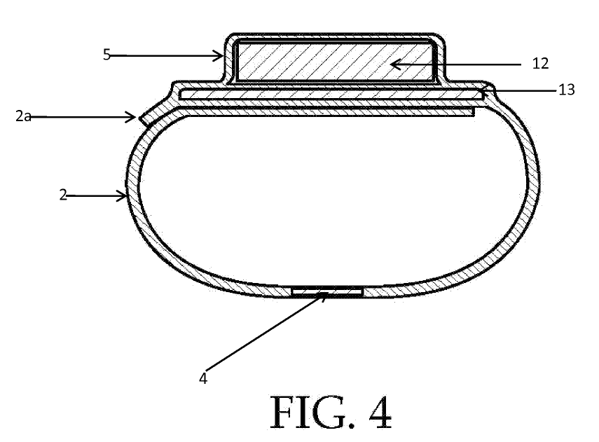

The hand/wrist mounted detector 1 contains two search coils 4 for detecting metal objects. A metal detection circuit 5 containing an internal wireless transmitter 12 (See FIG. 4) and a small rechargeable fuel cell 13 (See FIG. 4) is mounted on the detector 1. An operator activated “on” button/indicator 6 and an “off” button/indicator 7 are located on the metal detection circuit 5. The metal detection circuit 5 further displays a single coil indicator/selector 8 and a dual coil indicator/selector 9.

The hand/wrist mounted detector 1 of the subject invention is adjustable in size and may be mounted on either hand of an operator. The hand/wrist mounted detector 1 may have some flexibility to adapt to the shape of an operator's hand. In one embodiment of the subject invention, the hand/wrist mounted detector 1 is constructed of materials comprising leather, polypropylenes, such as nylon polypropylene and similar materials known to those skilled in the art.

In one embodiment of the subject invention, the internal wireless transmitter 12 comprises a Bluetooth® wireless transmitter or a similar transmitter known to those skilled in the art. In another embodiment of the subject invention, the small rechargeable fuel cell 13 comprises a NiH watch battery or a similar fuel cell known to those skilled in the art.

In one embodiment of the subject invention, the “on” button/indicator 6 and the “off” button/indicator 7 may comprises buttons, switches or other indicators known to those skilled in the art.

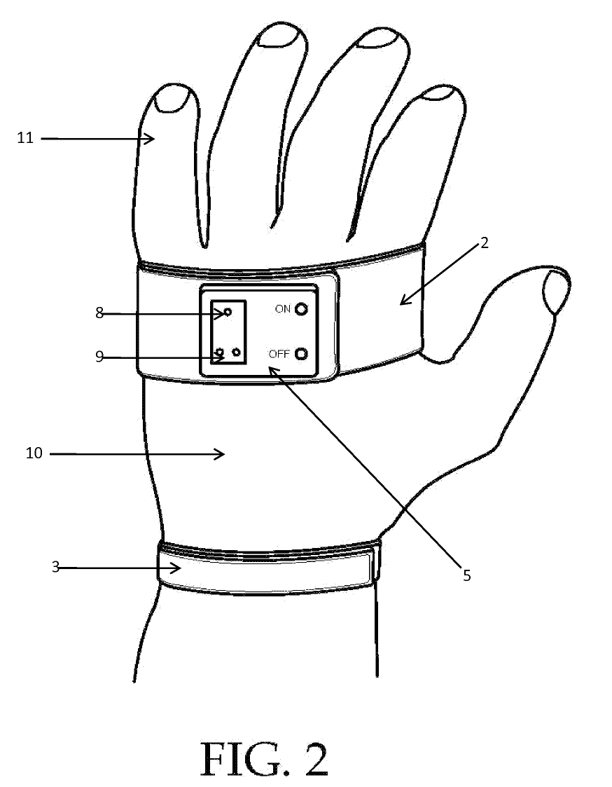

FIG. 2 illustrates a top view of this embodiment of the stealth detector metal detector 1 on an operator's hand 10. The hand-mounting strap 2 wraps around the palm of an operator's hand 10 below the operator's fingers 11. Both ends of the hand-mounting strap 2 are connected with button snaps 2a to form a loop around the palm of an operator's hand. The wrist mounting strap 3 wraps around the operator's wrist. Both ends of the wrist mounting strap 3 are connected with button snaps 3a to form a loop around the wrist of an operator's hand. In other embodiments of the subject invention, the hand-mounting strap 2 and the wrist mounting strap 3 may be connected by other fasteners such as Velcro®, buckles, magnets, snaps, buttons and tie straps. The metal detection circuit 5, the “on” button/indicator 6, the “off” button/indicator 7, the single coil indicator/selector 8 and the dual coil indicator/selector 9 are all easily viewable to the operator as he or she moves the two search coils 4 over a detainee.

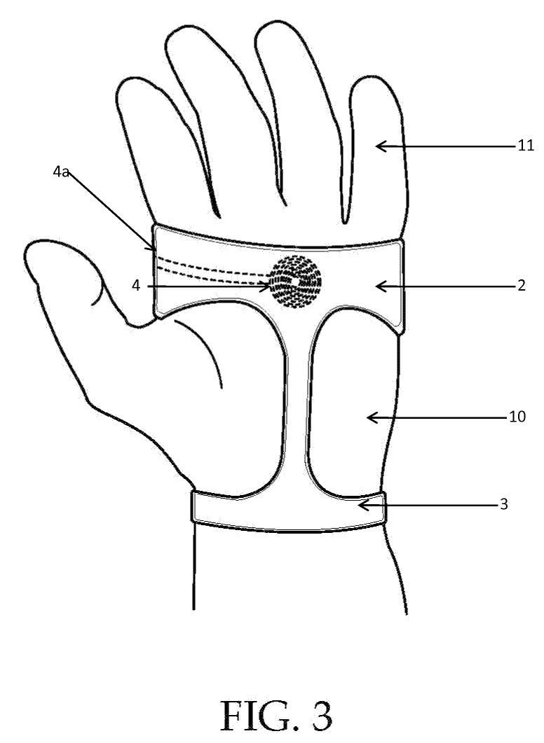

FIG. 3 illustrates a bottom view of this embodiment of the stealth detector metal detector 1 on an operator's hand 10. The hand-mounting strap 2 wraps around the palm of an operator's hand 10 below the operator's fingers 11. Both ends of the hand-mounting strap 2 are connected with button snaps 2a to form a loop around the palm of an operator's hand. The wrist mounting strap 3 wraps around the operator's wrist. Both ends of the wrist mounting strap 3 are connected with button snaps 3a to form a loop around the wrist of an operator's hand. The two search coils 4 are electrically coupled to the metal detection circuit 5 through wires 4a. The two search coils 4 will face a detainee when the detector 1 is in use. The two search coils 4 are also connected to the small rechargeable fuel cell 13 of the metal detection circuit 5 to receive electrical energy for operation.

FIG. 4 illustrates a side view of this embodiment of the stealth detector metal detector 1 in the closed position. The hand/wrist mounted detector 1 contains a hand-mounting strap 2 with button snaps 2a. Both ends of the hand-mounting strap 2 are connected with button snaps 2a to form a loop. The hand/wrist mounted detector also contains two search coils 4 for detecting metal objects. A metal detection circuit 5 containing an internal wireless transmitter 12 and a small rechargeable fuel cell 13 is mounted on the detector 1.

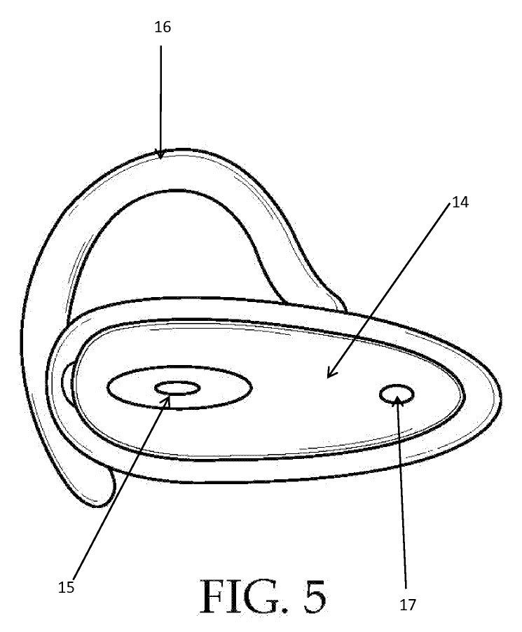

FIG. 5 illustrates a side view of an embodiment of a wireless headset receiver 14, which contains an on/off button 15, an ear connection piece 16 and a power indicator 17. In one embodiment of the subject invention, the wireless headset receiver 14 comprises a Bluetooth® wireless receiver or a similar receiver known to those skilled in the art.

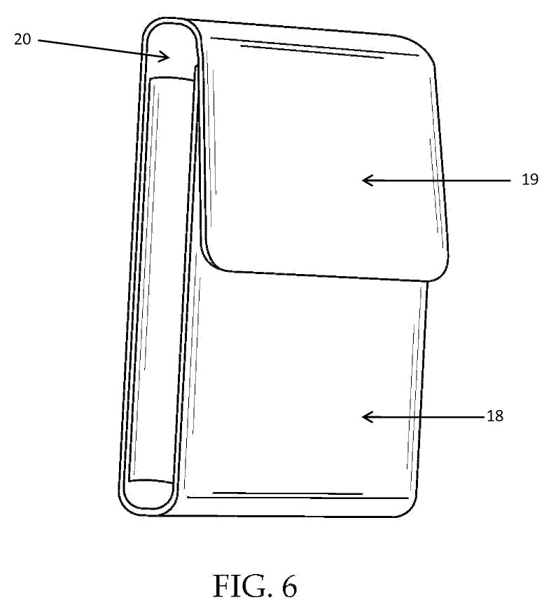

FIG. 6 illustrates a front view of an embodiment of a receiver housing 18. The housing receiver 18 contains a front flap 19 and an internal pocket 20. Within the internal pocket 20, the receiver housing 18 contains an adjustable vibration and/or audio alert circuitry electrically coupled to a built-in wireless receiver and a small rechargeable fuel cell. This housing receiver 18 may be worn anywhere on the user. In one embodiment of the subject invention, the built-in wireless receiver of the receiver housing 18 comprises a Bluetooth® wireless receiver or a similar receiver known to those skilled in the art.

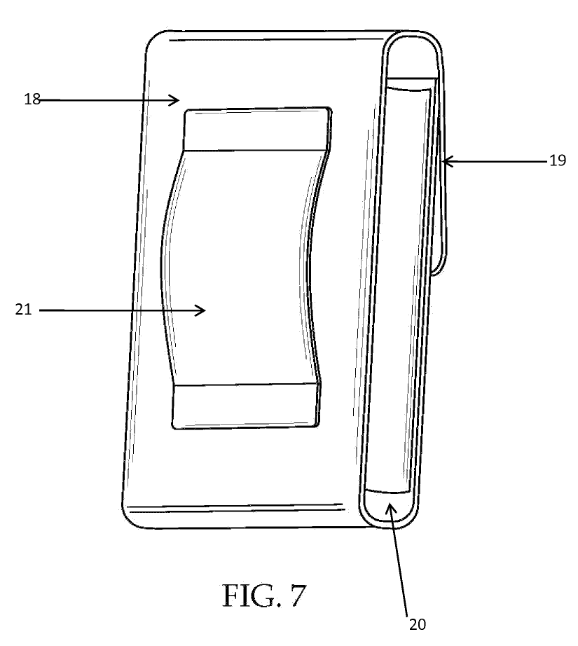

FIG. 7 illustrates a back view of this embodiment of the receiver housing 18. The housing receiver 18 contains a front flap 19, an internal pocket 20 and a belt clip 21.

To use the detector 1, an operator first charges the rechargeable fuel cell in the receiver housing 18 and the rechargeable fuel cell 13 in the metal detection circuit 5. Once both fuel cells are charged, the operator places the hand/wrist mounted detector 1 over his or her hand 10 by placing the search coils 4 on the palm of the hand. The operator then wraps the hand-mounting strap 2 around the back of the hand such that the metal detection circuit 5 rests on the back of the hand and connects the button snaps 2a. The operator then wraps the wrist mounting strap 3 around the wrist and connects the button snaps 3a. The operator activates the metal detection circuit 5 by pushing “on” button/indicator 6 and then selects the number of detecting coils to use by selecting either the single coil indicator/selector 8 or the dual coil indicator/selector 9.

The operator then places the housing receiver 18 somewhere on his or her body, away from the detector 1. In one embodiment of the subject invention, the operator may place the housing receiver 18 on his or her body using the belt clip 21. In another embodiment of the subject invention, the operator also places a wireless headset receiver 14 on his or her ear using the ear connection piece 16. The operator may adjust the vibration alert of the housing receiver 18. The operator may also adjust the audible volume of the housing receiver and/or the wireless headset receiver 14.

An operator searches a detainee by moving the search coils 4 on the palm side of the detector 1 over the detainee. Once the two search coils 4 detect a metal object on a detainee, these coils send an electrical signal to the metal detection circuit 5, which receives the signal, processes it, and directs the wireless transmitter 12 to send a transmission signal to the housing receiver 18, the wireless headset receiver 14, or both. The built-in wireless receiver of the receiver housing 18 receives the transmission signal and sends it to the vibration and/or audio alert circuitry. A received transmission signal causes the housing receiver 18 to vibrate, notifying the operator, but not the searched detainee, that a metal object has been detected.

A received transmission signal by the wireless receiver of the wireless headset receiver 14 causes it to issue a small audible sound, notifying the operator, but not the searched detainee, that a metal object has been detected.

In an additional embodiment of the subject invention, additional wireless receivers can be placed on additional operators to allow immediate notification of a detected metal object to multiple operators.

In a further embodiment of the subject invention, the wireless transmitter 12 of the metal detection circuit 5, built-in wireless receiver of the housing receiver 18 and the wireless headset receiver 14 will all be in sync for a given system of all three components. This will allow multiple operators within close proximity of one another to be using their own detector systems without interfering with other detector systems in use.

In another embodiment of the subject invention, the internal wireless transmitter 12 of the detector 1 may sync with and send detection signals to GPS devices. In another embodiment of the subject invention, the internal wireless transmitter 12 of the detector 1 may sync with and send detection signals to cellular phones.

What is claimed is:

1. A metal detector adapted for securement around a hand, wherein the metal detector comprises: a first strap, wherein the first strap comprises an adjustable means for connecting a first end of the first strap to a second end of the first strap to form a first loop around the palm of the hand; a second strap wherein the second strap comprises an adjustable means for connecting a first end of the second strap to a second end of second strap to form a second loop around the wrist of the hand; a third strap connecting the first strap and the second strap; a first search coil adapted for detecting metal and a second search coil adapted for detecting metal mounted on the first strap; a metal detection circuit mounted on the first strap, the metal detection circuit including a fuel cell and a wireless transmitter, wherein the metal detection circuit is operationally coupled to the first search coil, the second search coil and the wireless transmitter; further wherein when the first and second search coils detect metal, the first and second search coils send a metal detection signal to the metal detection circuit which sends a transmission signal to the wireless transmitter which emits a wireless signal.

2. The metal detector of claim 1, further comprising a wireless headset receiver, wherein the wireless headset receiver emits an audible sound after receiving the wireless signal from the wireless transmitter.

3. The metal detector of claim 1, further comprising a receiver housing, wherein the receiver housing comprises an adjustable annunciator electrically coupled to a wireless receiver, further wherein the adjustable annunciator emits an annunciation detectable to an operator after receiving the wireless signal from the wireless transmitter.

4. The receiver housing of claim 3, further comprising a second fuel cell.

5. The metal detector of claim 1, wherein the adjustable means for connecting the first end of the first strap to the second end of the first strap to form the first loop may be selected from the group consisting of Velcro, buckles, magnets, snaps, buttons and tie straps.

6. The metal detector of claim 1, wherein the adjustable means for connecting the first end of the second strap to the second end of the second strap to form the second loop may be selected from the group consisting of Velcro, buckles, magnets, snaps, buttons and tie straps.

7. The metal detector of claim 1, wherein the fuel cell is rechargeable.

8. The metal detector of claim 1, wherein the wireless transmitter is a Bluetooth transmitter.

9. The metal detector of claim 1, wherein the first strap, the second strap and the third strap comprise a unitary piece.

10. The metal detector of claim 1, wherein the first strap, the second strap and the third strap are constructed of nylon polypropylene.

11. The metal detector of claim 1, wherein the fuel cell comprises a NiH watch battery.

12. A method of detecting a metal object on a person, the method comprising the steps of:
a) securing a metal detector around a hand of an operator by connecting a first end of a first strap on the metal detector to a second end of the first strap to form a first loop around the palm of the hand;
b) connecting a first end of a second strap on the metal detector to a second end of the second strap to form a second loop around the wrist of the hand of the operator;
c) attaching a receiver housing to the operator;
d) activating the metal detector and the receiver housing;
e) passing a first search coil adapted for detecting metal and a second search coil adapted for detecting metal mounted on the first strap over the person;
f) detecting metal on the person, wherein the first and second search coils send a metal detection signal to a metal detection circuit on the metal detector which sends a transmission signal to a wireless transmitter in the metal detector circuit which emits a wireless signal; and
g) receiving the wireless signal through a wireless receiver in the receiver housing, wherein an adjustable annunciator in the receiver housing emits an annunciation that is detectable to the operator.

13. The method of claim 12, further comprising a wireless headset receiver, wherein the wireless headset receiver emits an audible sound after receiving the wireless signal from the wireless transmitter.

14. The method of claim 12, wherein the annunciation is a vibration.

15. The method of claim 12, wherein the annunciation is an audible sound.

16. The method of claim 12, wherein the wireless transmitter is a Bluetooth transmitter.

17. The method of claim 12, further comprising the step of receiving the wireless signal in a second receiver housing attached to a second operator.

18. The method of claim 12, further comprising the step of receiving the wireless signal in a plurality of other receiver housings attached to a plurality of other operators.

19. The method of claim 12, further comprising the step of receiving the wireless signal in a cellular phone.

20. The method of claim 12, further comprising the step of receiving the wireless signal in a GPS device.
